(19) United States
(12) Patent Application Publication
(10) Pub. No.: US 2025/0266350 A1
(43) Pub. Date: Aug. 21, 2025

(54) Layered Metallization in Power Semiconductor Packages

(71) Applicant: Wolfspeed, Inc., Durham, NC (US)

(72) Inventor: Afshin Dadvand, Durham, NC (US)

(21) Appl. No.: 18/443,031

(22) Filed: Feb. 15, 2024

(51) Int. Cl. H01L 23/528; H01L 23/00; H01L 23/532

(52) U.S. Cl. CPC H01L 23/5283; H01L 23/53219; H01L 23/53233; H01L 24/32; H01L 24/48; H01L 24/73; H01L 2224/32225; H01L 2224/48225; H01L 2224/73265; H01L 2924/12032; H01L 2924/13064; H01L 2924/13091; H01L 2924/181

(57) ABSTRACT

Semiconductor device packages are provided. In one example, the semiconductor device package includes a submount and a semiconductor die on the submount. In one example, the semiconductor die includes a semiconductor structure and a multilayer metallization structure on the semiconductor structure. The multilayer metallization structure includes a first metallization layer and a second metallization layer, which includes a different grain microstructure than the first metallization layer, on the first metallization layer. In one example, the first metallization layer and the second metallization layer include at least one common element.

### FIELD

The present disclosure relates generally to power semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or Group III nitride-based semiconductor materials.

### SUMMARY

Aspects and advantages of embodiments of the present disclosure will be set forth in part in the following description, or can be learned from the description, or can be learned through practice of the embodiments.

One example aspect of the present disclosure is directed to a semiconductor die. The semiconductor die includes a semiconductor structure and a multilayer metallization structure on the semiconductor structure. The multilayer metallization structure includes a first metallization layer and a second metallization layer on the first metallization layer. The second metallization layer has a different grain microstructure than the first metallization layer. The first metallization layer and the second metallization layer include at least one common chemical element.

Another example aspect of the present disclosure is directed to a semiconductor die. The semiconductor die includes a semiconductor structure and a multilayer metallization structure on the semiconductor structure. The multilayer metallization structure includes a first metallization layer and a second metallization layer on the first metallization layer. A smallest grain size of the first metallization layer is greater than about 100 nanometers, and a largest grain size of the second metallization layer is less than about 100 nanometers.

Another example aspect of the present disclosure is directed to a semiconductor device package. The semiconductor device package includes a submount and a semiconductor die on the submount. The semiconductor die includes a multilayer metallization structure. The multilayer metallization structure includes a first metallization layer having a thickness in a range of about 100 nanometers to about 2 microns and a second metallization layer having a thickness in a range of about 100 nanometers to about 2 microns on the first metallization layer. The first metallization layer includes aluminum, and the second metallization layer includes an aluminum alloy.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a perspective view of a semiconductor device including a multilayer metallization structure according to example embodiments of the present disclosure;

FIG. 2 depicts a cross-sectional view of a semiconductor device according to example embodiments of the present disclosure;

FIG. 3A depicts a cross-sectional view of an example multilayer metallization structure according to example embodiments of the present disclosure;

FIG. 3B depicts a cross-sectional view of an example multilayer metallization structure according to example embodiments of the present disclosure;

FIG. 4A depicts a cross-sectional view of an example multilayer metallization structure according to example embodiments of the present disclosure;

FIG. 4B depicts a cross-sectional view of an example multilayer metallization structure according to example embodiments of the present disclosure;

FIG. 4C depicts a cross-sectional view of an example multilayer metallization structure according to example embodiments of the present disclosure;

FIG. 5 depicts an example semiconductor package of a semiconductor device according to example embodiments of the present disclosure; and

FIG. 6 depicts an example semiconductor package of a semiconductor device according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor device packages (e.g., discrete semiconductor device packages and power modules) have been developed that include a semiconductor die, such as a metal-oxide-semiconductor field-effect transistor (MOSFET), a Schottky diode, and/or a high electron mobility transistor (HEMT) device. Semiconductor device packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Semiconductor device packages with Schottky diodes and/or HEMT devices may be employed in many of the same high-performance power applications described above for MOSFETs, sometimes in systems that also include discrete power packages of MOSFETs.

Example aspects of the present disclosure are directed to semiconductor device packages for use in semiconductor applications and other electronic applications. It should be understood that the terms “semiconductor device package” and “semiconductor package” may be used interchangeably. In some examples, semiconductor device packages may include one or more semiconductor die. The one or more semiconductor die may include a wide bandgap semiconductor material. A wide bandgap semiconductor has a band gap greater than about 1.40 eV, such as silicon carbide and/or a Group-III nitride (e.g., gallium nitride).

In some examples, the one or more semiconductor die may include one or more semiconductor devices, such as transistors, diodes, and/or thyristors. For instance, in some examples, the one or more semiconductor die may include a MOSFET, such as a silicon carbide-based MOSFET. Additionally and/or alternatively, in some examples, the one or more semiconductor die may include a Schottky diode, such as a silicon carbide-based Schottky diode. Additionally and/or alternatively, in some examples, the one or more semiconductor die may include a HEMT device, such as a Group-III nitride-based HEMT device.

It should be understood that aspects of the present disclosure are discussed with reference to silicon carbide-based MOSFET devices for purposes of illustration and discussion. Those having ordinary skill in the art, using the disclosures provided herein, will understand that the power semiconductor package of the present disclosure may include other power semiconductor devices without deviating from the scope of the present disclosure, such as diodes (e.g., Schottky diodes, PiN diodes, etc.), insulated gate bipolar transistors, HEMTs, or other devices.

In some semiconductor packages, the one or more semiconductor die may be attached to a submount (e.g., lead frame) by a die-attach material between the one or more semiconductor die and the submount. For instance, in some examples, a die-attach material may be deposited on the submount, and the semiconductor die (or other component) may be placed on the die-attach material, and the die-attach material may be subjected to bonding or a bonding process (e.g., sintering) to secure the semiconductor die (or other component) to the die-attach material. Various types of die-attach material may be used to bond the one or more semiconductor die to the submount such as, for instance, metal sintering die-attach (e.g., silver (Ag) or copper (Cu)) and conductive adhesive die-attach. Additionally and/or alternatively, in some examples, the semiconductor package may use wire bond(s) (e.g., aluminum wire bond(s)) for interconnection between portions of the one or more semiconductor die (e.g., a gate contact) and the package (e.g., lead frame). Furthermore, in some examples, a passivation layer may be provided on the one or more semiconductor die, such as a silicon nitride and/or polyimide passivation layer.

The semiconductor package may further include a housing in which the one or more semiconductor die may be arranged. The semiconductor package may also include one or more electrical leads extending from the housing. More particularly, in some examples, the housing may be an encapsulating portion (e.g., epoxy mold compound (EMC)) formed around at least a portion of the submount and the one or more semiconductor die.

The one or more semiconductor die may further include one or more metallization structures. A “metallization structure” is any layer, structure, or other portion of a semiconductor die that incorporates a metal for thermal and/or electrical conduction. Metallization structures in a semiconductor device may be used, for instance, to provide an electrically conductive and/or thermally conductive connection to the one or more semiconductor die. The metallization structure may include, for instance, one or more electrodes, contacts, interconnections, bonding pads, backside layers, metal layers, or metal coatings of the semiconductor device on the semiconductor die.

Power semiconductor devices may experience anomalies and/or degradation resulting from the deformation, delamination, shifting, moving (e.g., glacial moving) of copper and/or aluminum metallization structures (including copper-aluminum alloys). As used herein, the term “alloy” refers to a mixture of metal elements. In addition, cracks in a passivation layer of the power semiconductor device may result from thermomechanical stress to a semiconductor die surface during different reliability tests, such as thermal cycling (TC) tests.

For instance, some passivation layers include, e.g., polyimide, silicon nitride (SiNₓ) and/or silicon oxide (SiOₓ). During thermal cycling (TC) tests, epoxy mold compounds (EMCs) may induce a shear stress to such passivation layers, which may subsequently be transferred to underlying layers and structures, such as the metallization structures, semiconductor die, submount, and the like. Furthermore, the shear stress induced in the passivation layer may concentrate at an interface with the underlying layers and structures, such as at the edges of the metallization structures and/or semiconductor die, leading to deformation, delamination, and/or ratcheting of metallization structures and semiconductor die. For instance, the thermomechanical induced shear stress may build up and cascade with each thermal cycle, which may result in plastic deformation of the metallization structures due to their relatively low yield strength compared to the induced shear stress. This phenomenon—which may be referred to as as “ratcheting”—may result in glacial moving and/or delamination of the metallization structures, as well as cracking of the passivation layer.

Moreover, microstructural changes may be initiated and may increase during thermal cycling (TC), which may cause hillocks to develop, cracks to form, and/or delamination at the grain boundaries of the metallization structures. These structural degradations may intensify as a thickness of the metallization structure is increased to achieve higher ampacity (e.g., via copper (Cu) wires/clips and/or aluminum (Al) wire bonds).

In some power semiconductor device packages, an aluminum-copper alloy has been introduced as an alternative metallization material for metallization structures relative to aluminum. The aluminum-copper alloy may exhibit slightly higher resistance to metal deformation as well as higher resistance to metal corrosion in the presence of ionic impurities. However, metallization structures based on an aluminum-copper alloy may suffer from residual stress, thermal stress relaxation, and accelerated galvanic corrosion of aluminum, particularly at an interface with a connection structure such as a wire bond. Moreover, a coefficient of thermal expansion (CTE) mismatch between the metallization structure and other parts of semiconductor die, including a silicon nitride/oxide passivation layer or other passivation layer (e.g., polyimide passivation layer), is still of concern.

Aluminum-copper alloy is also vulnerable to damage in high power wire-bonding processes where a thick aluminum wire (e.g., 15 mil or 20 mil) or copper wire is used to achieve higher ampacity. This may induce further damage to the semiconductor die. The damage may be even more pronounced with bonding pads having a smaller thickness (e.g., about 4 μm). Increased metallization pad thickness (e.g., about 5 μm to about 6 μm), on the other hand, may have adverse effects such as risk of metal migration. Moreover, the diffusion of copper to the semiconductor die when an aluminum copper alloy is used for metallization structure may cause reliability concerns.

To address the shear stress concerns discussed above, some power semiconductor device packages include metallization structures having separated metallization layers. More particularly, some power semiconductor device packages include layers of aluminum and/or aluminum-copper alloys with thin layers (e.g., about 10 nanometers to about 20 nanometers) of hard metal (e.g., titanium (Ti), nickel (Ni), palladium (Pd)) designed to carry the shear stress stacked therebetween. However, introducing these hard metal layers may significantly affect the thermomechanical and microstructural properties of the metallization structure. For instance, introducing such hard metal layers may significantly (negatively) alter conductivity, bond-ability, adhesion, corrosion, elemental diffusion, precipitation, and/or alloying with other underlying layers of the metallization structure.

Accordingly, example aspects of the present disclosure provide semiconductor die and semiconductor device packages having a semiconductor structure and a multilayer metallization structure on the semiconductor structure. More particularly, a multilayer metallization structure according to examples of the present disclosure may include a first metallization layer and a second metallization layer. In some examples, the second metallization layer may include a different grain microstructure than the first metallization layer. Furthermore, as described in greater detail below, multilayer metallization structures according to the present disclosure may include a plurality of first metallization layers and a plurality of second metallization layers. For instance, in some examples, the multilayer metallization structure may include at least four layers (e.g., two first metallization layers, two second metallization layers). In some examples, the multilayer metallization structure may include at least six layers (e.g., three first metallization layers, three second metallization layers).

In some examples, the first metallization layer and the second metallization layer may include at least one common chemical element, such as aluminum. For instance, in some examples, the multilayer metallization structure may include a layered metal deposition of aluminum and an aluminum alloy, such as an aluminum-copper (AlCu) alloy, an aluminum-magnesium (AlMg) alloy, an aluminum-beryllium (AlBe) alloy, and the like (e.g., aluminum alloys having a non-aluminum elemental concentration in a range of about 0.1% to about 1% and/or a range of about 1% to about 5%). In some examples, the multilayer metallization structure may include a layered metal deposition of any combination of different aluminum alloys (e.g., AlMg-AlCu, AlBe-AlCu, AlBe-AlMg) or their ternary compositions, such as silicon (Si), cobalt (Co), and the like.

It should be understood that, as used here, “different” aluminum alloys refer to aluminum alloys having different microstructures and grain sizes. For instance, an aluminum-copper alloy is a “different” aluminum alloy than, e.g., aluminum-magnesium and aluminum-beryllium. Put differently, in some examples, the first metallization layer may have a first grain microstructure having a smallest grain size of greater than about 100 nanometers (e.g., about 100 nanometers to about 500 nanometers), and the second metallization layer may have a second grain microstructure having a largest grain size of less than about 100 nanometers (e.g., about 20 nanometers to about 100 nanometers). As such, in some examples, a difference between the smallest grain size of the first metallization layer (e.g., of the first grain microstructure) and the largest grain size of the second metallization layer (e.g., of the second grain microstructure) may be approximately 100 nanometers. Furthermore, each metal and/or metal alloy exhibits a crystalline structure consisting of atoms arranged in an ordered pattern. The grains represent individual crystalline regions within the alloy, and the nature of their arrangement affects the mechanical and thermal properties of the respective metal/metal alloy. A metal/metal alloy having a “different” grain structure refers to a metal/metal alloy having different grain properties. Grain properties may include, for instance, grain size, grain boundary characteristics, grain orientation, and the like.

Furthermore, the multilayer metallization structures described herein may include metallization layers having a limited thickness (e.g., about 100 nanometers (nm) to about 2 microns (μm)) to control and tune the microstructure of the multilayer metallization structure and, thus, the mechanical properties of each its metallization layers. As such, in some examples, the multilayer metallization structure may have a combined thickness greater than about 1 micron. In this manner, the overall yield strength of the multilayer metallization structure (with respect to shear stress) may be increased, and the shear stress may be distributed into the bulk of the multilayer metallization structure at each layer therein and to underlying layers. More particularly, due to the Hall-Patch effect, reducing the thickness of the multilayer metalation structure (and its respective layers) may limit the metal grain growth and, in turn, increase the overall mechanical (yield) strength.

Aspects of the present disclosure provide a number of technical effects and benefits. For instance, multilayer metallization structures according to examples of the present disclosure may address different reliability challenges in high performance semiconductor packaging, such as aluminum splash out, pad cratering, galvanic corrosion, passivation layer cracks, and the shift or deformation of metallization structures. Furthermore, such multilayer metallization structures may exhibit similar CTE values to that of different parts of the semiconductor die, while being resistant to the mechanical stresses posed by, for instance, the encapsulating material (e.g., EMC) of the semiconductor device package. Moreover, due to improved structural robustness of such multilayer metallization structures, these alloys may increase the reliability of wire bonding processes and may allow for the reduction in thickness of the multilayer metallization structure (e.g., thickness of the bonding pads) without risk of damaging the underlying layers in the semiconductor die during a wire bonding process.

Additionally, by providing for a layered metal deposition, example aspects of the present disclosure allow the grain microstructure and mechanical properties of each of the metallization layers in the multilayer metallization structure to be controlled and/or tuned. In this manner, the shear stress is distributed to the bulk of the multilayer metallization structure. Furthermore, the low metal thickness of the multilayer metallization structure and its respective metallization layers increases the overall yield strength of each metallization layer (versus shear stress) which, in turn, drastically reduces thermomechanical-induced failures. Multilayer metallization structures having low metal thickness also limits metal grain growths, especially when, as described herein, aluminum and/or aluminum-copper is alloyed with beryllium and/or magnesium. More particularly, alloying aluminum and/or aluminum-copper with beryllium and/or magnesium has a synergic effect on limiting grain growth because such alloys increase the recrystallization temperature of the multilayer metallization structure by more than, e.g., 100° C.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

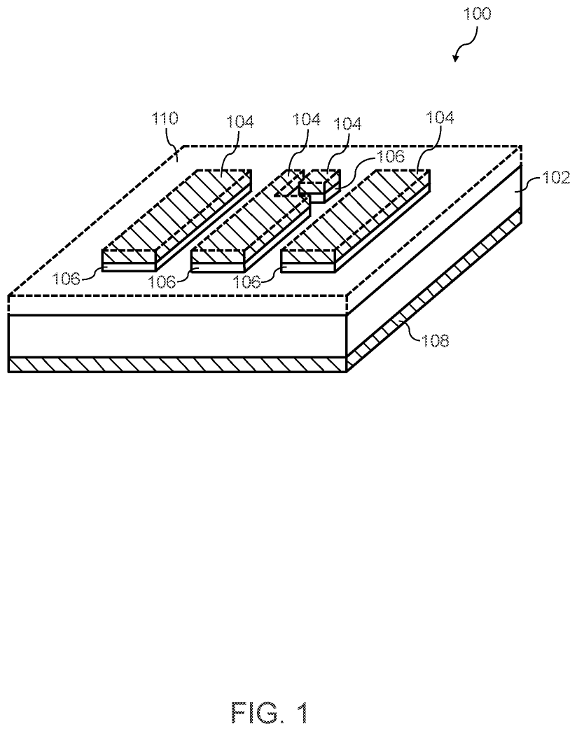

FIG. 1 depicts an example semiconductor device 100 according to example embodiments of the present disclosure. The semiconductor device 100 may include, for instance, one or more semiconductor die 102. The one or more semiconductor die 102 may include a semiconductor structure, such as a wide bandgap semiconductor. By way of non-limiting example, the wide bandgap semiconductor may include a silicon carbide structure and/or a Group-III nitride (e.g., GaN, AlGaN, etc.) structure. For instance, the one or more semiconductor die 102 may include one or more silicon carbide-based MOSFETs, one or more silicon carbide-based Schottky diodes, one or more Group-III nitride-based HEMTs, etc. The one or more semiconductor die 102 may include one or more epitaxial layers formed on a substrate, such as a silicon carbide substrate.

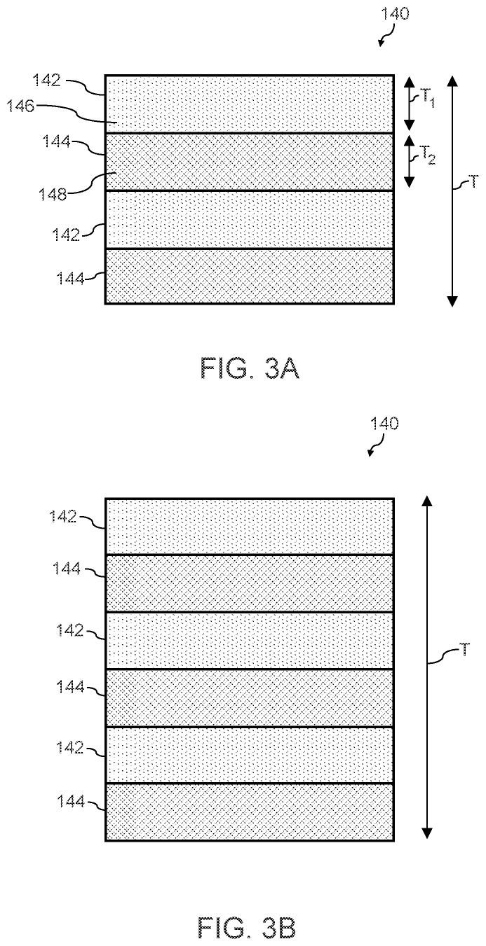

The semiconductor device 100 may include one or more metallization structures on the semiconductor die 102 (e.g., on the semiconductor structure). As will be discussed in greater detail below, the one or more metallization structures on the semiconductor structure of the semiconductor die 102 may be one or more multilayer metallization structures 140 (FIGS. 3A-3B).

The one or more multilayer metallization structures 140 may include, for instance, bonding pads 104. Bonding pads 104 may be used to make an electrical connection to the semiconductor device 100 using connection structures, such as wire bonds. The bonding pads 104 may be arranged on an adhesion layer 106 to secure the bonding pads 104 to the one or more semiconductor die 102 to provide, for instance, a gate connection, source connection, kelvin connection, sensor connection, or other suitable connection. The adhesion layer 106 may be, for instance, titanium. The bonding pads 104 may have a thickness of about 4 microns (4 μm) or less in some embodiments.

In some examples, the semiconductor device 100 may include one or more multilayer metallization structures 140 on different surfaces of the semiconductor die 102. For instance, by way of non-limiting example, the semiconductor device 100 may also include a backside metallization structure 108 on the one or more semiconductor die 102. In some semiconductor packages, the backside metallization structure 108 may be secured to a submount (e.g., a lead frame of a semiconductor package) using, for instance, a die-attach material to provide a thermal and/or electrical connection for the semiconductor device 100 (e.g., a drain connection). More particularly, in some examples, the submount may include copper. For instance, the submount may include a direct bonded copper (DBC) substrate, an active metal brazed (AMB) substrate, and/or other power substrate. Furthermore, the die-attach material may include a sintered material, such as sintered silver or sintered copper. In this manner, the one or more semiconductor die 102 may be on the submount.

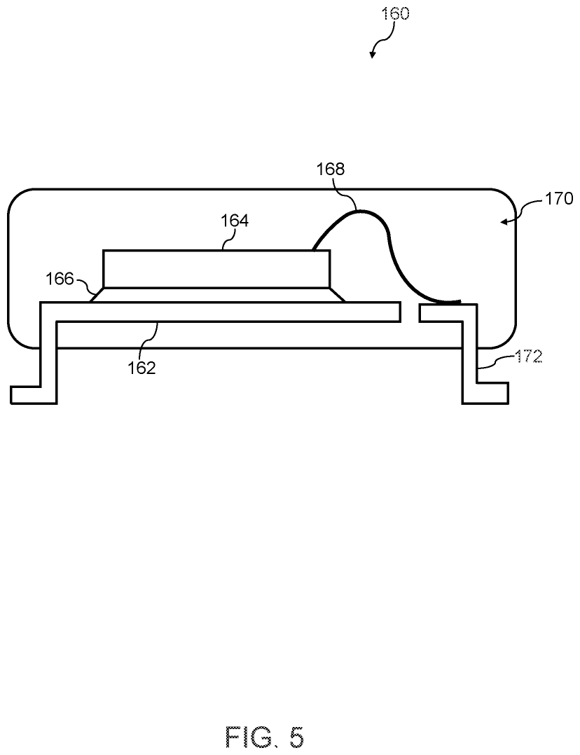

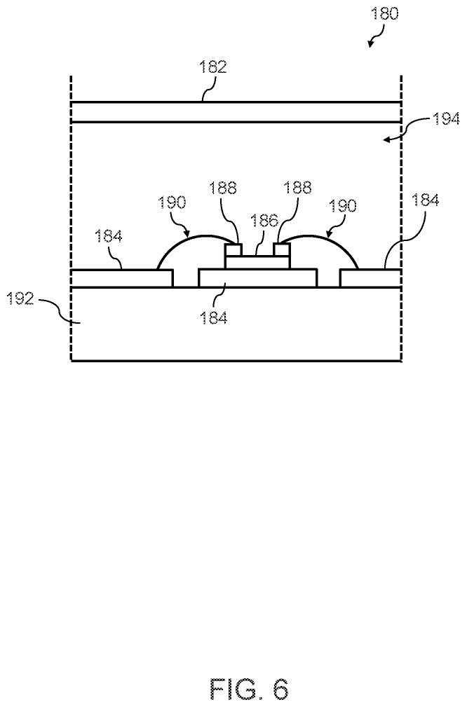

It should be understood that, although depicted in FIG. 1 as the bonding pads 104 and the backside metallization structure 108, the one or more multilayer metallization structures 140 may be any layer, structure, or other portion of the semiconductor device 100, semiconductor die 102, or semiconductor package (e.g., semiconductor package 160 (FIG. 5), semiconductor package of semiconductor device 180 (FIG. 6)) that incorporates a metal to provide an electrically conductive and/or thermally conductive connection to the one or more semiconductor die 102. For instance, by way of non-limiting example, the one or more multilayer metallization structures 140 may be an electrode for the semiconductor structure, such as a gate electrode, a source electrode, a drain electrode, and the like. Additionally and/or alternatively, in some examples, the multilayer metallization structure 140 may be an interconnect, a metal layer, and/or a metal coating for the semiconductor device 100. As such, those having ordinary skill in the art, using the disclosures provided herein, will understand that the one or more multilayer metallization structures 140 may be any suitable multilayer metallization structure without deviating from the scope of the present disclosure.

The semiconductor device 100 may include a passivation layer 110. The bonding pads 104 may be exposed through openings in the passivation layer 110. The passivation layer 110 may include one or more suitable passivation materials, such as silicon nitride. In some examples, the passivation layer 110 may be a polymer, such as polyimide. In some examples, the passivation layer 110 may be SiO₂, MgOx, MgNx, ZnO, SiNx, SiOx, or other dielectric material.

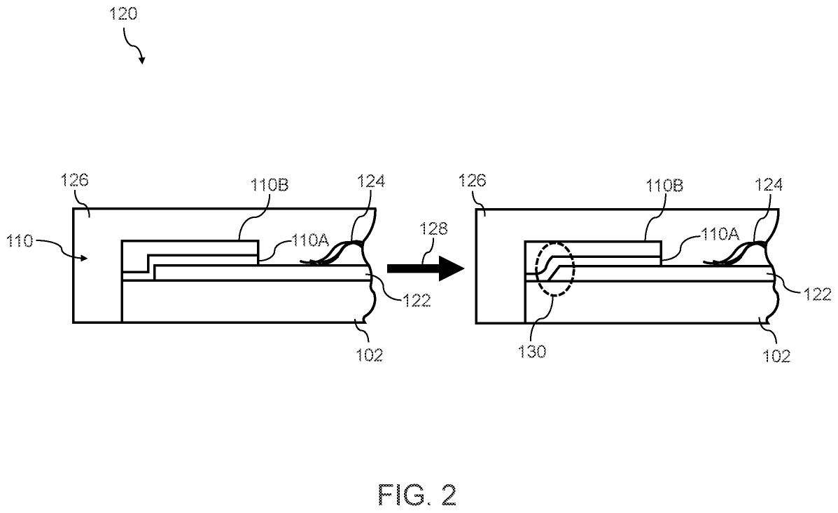

Referring now to FIG. 2, a cross-sectional view of a semiconductor device 120 is depicted according to example embodiments of the present disclosure. FIG. 2 depicts a portion of the semiconductor device 120 and is intended to represent structures for identification and description. However, FIG. 2 is not intended to represent the structures of the semiconductor device 120 to physical scale.

The semiconductor device 120 of FIG. 2 may be similar to the semiconductor device 100 discussed above with reference to FIG. 1. For instance, the semiconductor device 120 may include the semiconductor die 102. As described above, the semiconductor die 102 may be attached to a submount (e.g., lead frame) (not shown).

The semiconductor device 120 may also include the passivation layer 110. As shown, the passivation layer 110 may include one or more suitable passivation materials, such as a silicon nitride layer 110A. In some examples, the passivation layer 110 may also include a polymer layer 110B, such as polyimide. In some examples, the passivation layer 110 may be SiO₂, MgOx, MgNx, ZnO, SiNx, SiOx, or other dielectric material.

Furthermore, the semiconductor device 120 may also include a metallization structure 122 on the semiconductor die 102. The metallization structure 122 may be exposed through openings in the passivation layer 110. Although not depicted in FIG. 2 for case of illustration, the metallization structure 122 may be attached to the semiconductor die 102 (e.g., using an adhesion layer and/or a die-attach material) to provide a thermal and/or electrical connection for the semiconductor device 120. For instance, in some examples, the metallization structure 122 may be an electrode (e.g., gate electrode, source electrode, drain electrode) for a semiconductor structure (not shown) of the semiconductor die 102. Additionally and/or alternatively, in some examples, the metallization structure 122 may be an interconnect and/or a bonding pad (e.g., bonding pad 104 (FIG. 1)) for the semiconductor structure of the semiconductor die 102. The metallization structure 122 may be used to make an electrical connection to the semiconductor device 120 using a connection structure, such as, by way of non-limiting example, one or more wire bonds 124.

As will be discussed in greater detail below (e.g., FIGS. 5-6), the semiconductor device 120 may be arranged within a housing. More particularly, in some examples, the housing may be an encapsulating portion 126 (e.g., epoxy mold compound (EMC)) formed around at least a portion of the submount (not shown) and the semiconductor die 102, including the metallization structure 122. In this manner, the semiconductor device 120 may be arranged within a semiconductor device package, such as the semiconductor device package 160 (FIG. 5) and/or the semiconductor device package 180 (FIG. 6).

Semiconductor devices, such as the semiconductor device 100 (FIG. 1) and the semiconductor device 120 (FIG. 2), often undergo a variety of reliability tests, such as thermal cycling (TC). Thermal cycling is commonly used to stress test the microstructural reliability and durability of microelectronic devices, such as the semiconductor devices and packages disclosed herein. In particular, thermal cycling is a process of subjecting semiconductor devices/materials to repeated, quick cycles of alternating extreme temperature changes to simulate real-world operating conditions. In this manner, thermal cycling may be used to identify potential reliability issues of the semiconductor devices/materials, such as thermomechanical-induced failures. As one example, thermal cycling tests may be used to determine CTE mismatches between components and the respective sensitivity of the device due to the CTE mismatches. However, due to the extreme temperature fluctuations, some semiconductor devices may experience a variety of anomalies and/or failures resulting from the thermal cycling itself.

As an illustrative example, FIG. 2 depicts the semiconductor device 120 before and after thermal cycling, which is represented by arrow 128 (hereinafter TC test 128). As described above, the semiconductor device 120 may include the metallization structure 122 attached to the semiconductor die 102 to provide a thermal and/or electrical connection for the semiconductor device 120. In contrast to the multilayer metallization structure 140 discussed below (FIGS. 3A-3B), the metallization structure 122 depicted in FIG. 2 may include a single metallization layer that includes, for instance, copper and/or aluminum. In some examples, the metallization structure 122 may include a single layer of a copper-aluminum alloy. In other examples, the metallization structure 122 may include multiple copper, aluminum, and/or aluminum-copper layers with thin metallization layer therebetween. For instance, the thin metallization layer may include, for instance, nickel and/or titanium and/or palladium, between the other aluminum, copper, and/or aluminum-copper layers.

As noted above, the extreme temperature fluctuations and thermomechanical stress induced during the TC test 128 may damage the semiconductor device 120, particularly at interfaces between different structures/materials of the semiconductor device 120. For instance, during the TC test 128, the encapsulating portion 126 (e.g., epoxy mold compound (EPC)) may induce thermomechanical (e.g., shear) stress to the passivation layer 110. In addition to causing cracks (not shown) in the passivation layer 110 itself, the shear stress on the passivation layer 110 may subsequently be transferred to underlying layers and structures of the semiconductor device 120, such as the metallization structure 122, the semiconductor die 102, the submount (not shown), and the like.

The shear stress induced in the passivation layer 110 may also concentrate at one or more interfaces with the underlying layers and structures of the semiconductor device 120, such as interface 130 between the passivation layer 110 and the edges of metallization structure 122 and semiconductor die 102. The induced shear stress at the interfaces may lead to deformation, delamination, and/or ratcheting of the metallization structure 122 and the semiconductor die 102. For instance, the induced shear stress may build up and cascade with each thermal cycle of the TC test 128, which, as shown at interface 130, may result in plastic deformation of the metallization structure 122 due to its low yield strength (e.g., of copper and/or aluminum) compared to the induced shear stress. Otherwise known as “ratcheting,” this phenomenon may cause glacial moving and/or delamination of the metallization structure 122 at interface 130, as well as the cracking of the passivation layer 110. Moreover, as will be discussed in greater detail below, the TC test 128 may also initiate microstructural changes in the metallization structure 122. The induced microstructural changes intensify with each thermal cycle of the TC test 128, which may lead to the development of hillocks, the formation of cracks, and/or delamination along grain boundaries of the metallization structure 122.

In examples where the metallization structure 122 includes a single layer of aluminum, copper, or an aluminum-copper alloy, the metallization structure 122 is vulnerable to damage during high power wire-bonding processes where thick wire bonds 124 (e.g., of aluminum and/or copper) are used to achieve higher ampacity. The resulting damage to the semiconductor device 120 is further pronounced when a thickness of the metallization structure 122 is decreased, but increasing the thickness of the metallization structure 122 may adversely affect the metallization structure 122 by increasing, for instance, a risk of metal migration and/or diffusion.

In examples where the metallization structure 122 also includes a thin metallization layer (e.g., nickel, titanium, palladium) stacked between the other aluminum, copper, and/or aluminum-copper layers, the metallization structure 122 is still vulnerable to the thermomechanical stress-related issued described above. For instance, although the thin metallization layer is designed to carry the shear stress, the hard metals therein may adversely affect the thermomechanical and microstructural properties of the metallization structure 122 by altering the conductivity, bond-ability, adhesion, elemental diffusion, precipitation, and/or alloying with other underlying layers in the metallization structure 122.

Hence, a semiconductor device and package that addresses the aforementioned thermomechanical stress-related issues without adversely affecting the thermomechanical and microstructural properties of the metallization structures is desired. Accordingly, referring briefly to FIG. 1, the semiconductor device 100 may include one or more multilayer metallization structures 140 (FIGS. 3A-3B) on the semiconductor structure (e.g., semiconductor die 102) which, as discussed in greater detail below, address the aforementioned thermomechanical stress-related issues without adversely affecting the thermomechanical and microstructural properties of the multilayer metallization structure 140 itself. As noted above, the one or more multilayer metallization structures 140 may be any suitable metallization structure, such as an electrode, an interconnect, a bonding pad, and the like.

Referring now to FIGS. 3A-3B, cross-sectional views of example multilayer metallization structures 140 are depicted according to example embodiments of the present disclosure. FIGS. 3A-3B are intended to represent structures for identification and description and is not intended to represent the structures to physical scale. The multilayer metallization structure 140 depicted in FIGS. 3A-3B may correspond to the bonding pads 104 (FIG. 1) and/or the backside metallization structure 108 (FIG. 1). However, in some examples, the multilayer metallization structure 140 may be an electrode for the semiconductor structure, such as a gate electrode, a source electrode, a drain electrode, and the like. Additionally and/or alternatively, in some examples, the multilayer metallization structure 140 may be an interconnect, a metal layer, and/or a metal coating for the semiconductor device 100. Thus, it should be understood that the multilayer metallization structure 140 may be any suitable metallization structure for a semiconductor structure without deviating from the scope of the present disclosure.

As shown, the multilayer metallization structure 140 may include a first metallization layer 142 and a second metallization layer 144. In some examples, the first metallization layer 142 may have a thickness T₁ in a range of about 100 nanometers to about 2 microns, and the second metallization layer 144 may have a thickness T₂ in a range of about 100 nanometers to about 2 microns. In some examples, such as that depicted in FIGS. 3A-3B, the thickness T₁ of the first metallization layer 142 may be substantially equal to the thickness T₂ of the second metallization layer 144. In other examples, although not depicted in FIGS. 3A-3B for case of illustration, the thickness T₁ of the first metallization layer 142 may be different than the thickness T₂ of the second metallization layer 144. As such, the multilayer metallization structure 140 may have a combined thickness T greater than about 1 micron, such as about 4 microns.

As shown in FIGS. 3A-3B, the multilayer metallization structure 140 may include a plurality of first metallization layers 142 and a plurality of second metallization layers 144, with each first metallization layer 142 and each second metallization layer 144 being alternatively arranged in a stacked arrangement. For instance, by way of non-limiting example, the multilayer metallization structure 140 may include two first metallization layers 142 alternately arranged between two second metallization layers 144. Additionally and/or alternatively, in some examples, the multilayer metallization structure 140 may include three first metallization layers 142 alternately arranged between three second metallization layers 144. Thus, as shown in FIGS. 3A-3B, the multilayer metallization structure 140 may be a multilayer metallization stack with at least four metallization layers (FIG. 3A), such as at least six metallization layers (FIG. 3B).

It should be understood that the multilayer metallization structures 140 are depicted in FIGS. 3A-3B with four metallization layers (FIG. 3A) and six metallization layers (FIG. 3B) for purposes of illustration and discussion. Those having ordinary skill in the art, using the disclosures provided herein, will appreciate that multilayer metallization structures according to the present disclosure may include any number of metallization layers without deviating from the scope of the present disclosure.

To address the thermomechanical stress-related issues discussed above (e.g., FIG. 2), the first metallization layer 142 may include a first grain microstructure 146 and the second metallization layer 144 may include a second grain microstructure 148 that is different from the first grain microstructure 146. More particularly, the first grain microstructure 146 may have a smallest grain size of greater than about 100 nanometers. For instance, in some examples, the first grain microstructure 146 may have a smallest grain size in a range of about 100 nanometers to about 500 nanometers, such as greater than about 200 nanometers, such as a range of about 200 nanometers to about 300 nanometers. Additionally, the second grain microstructure 148 may have a largest grain size of less than about 100 nanometers. For instance, in some examples, the second grain microstructure 148 may have a largest grain size in a range of about 20 nanometers to about 100 nanometers. Furthermore, in some examples, a difference between the smallest grain size of the first grain microstructure 146 and the largest grain size of the second grain microstructure 148 may be about 100 nanometers.

By providing the first metallization layers 142 and the second metallization layers 144 with limited thicknesses T₁ and T₂ (respectively), the microstructure of the multilayer metallization structure 140 (and the metallization layers 142, 144) may be controllable and tunable. In this manner, in contrast to the metallization structure 122 discussed above with reference to FIG. 2, the overall yield strength (with respect to shear stress) of the multilayer metallization structure 140 may be increased. More particularly, as described above, reducing the thickness of the multilayer metallization structure 140 (and the metallization layers 142, 144) may limit the metal grain growth of the first grain microstructure 146 and the second grain microstructure 148. Thus, the overall mechanical (yield) strength of the multilayer metallization structure 140 is increased. Moreover, the shear stress (e.g., induced by TC test 128) may be distributed into the bulk of the multilayer metallization structure 140 at each metallization layer (e.g., first metallization layer 142, second metallization layer 144) and to other underlying layers and structures of the semiconductor device 100 (e.g., semiconductor die 102, submount, etc.). In this manner, because of the multilayer metallization structure 140, occurrences of thermomechanical-induced failures in the semiconductor device 100 (FIG. 1) are drastically reduced compared to the semiconductor device 120 (FIG. 2).

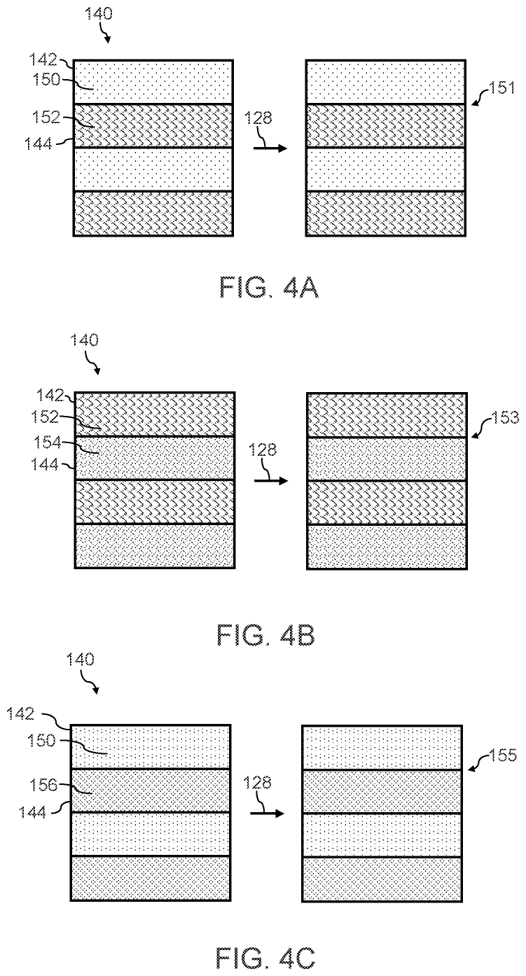

Referring now to FIGS. 4A-4C, cross-sectional views of various configurations of the example multilayer metallization structures 140 of FIG. 3 are depicted according to example embodiments of the present disclosure. More particularly, as illustrative examples, FIGS. 4A-4C depict example configurations of the first metallization layer 142 and the second metallization layer 144 of the multilayer metallization structure 140. FIGS. 4A-4C are intended to represent structures for identification and description and are not intended to represent the structures to physical scale. Furthermore, it should be understood that the example configurations depicted in FIGS. 4A-4C and described below are for purposes of illustration and discussion. Those having ordinary skill in the art, using the disclosures provided herein, will understand that the multilayer metallization structure 140 may include different chemical elements and/or configurations without deviating from the scope of the present disclosure.

In some examples, such as those depicted in FIGS. 4A-4B, the first metallization layer 142 and the second metallization layer 144 may include at least one common chemical element. More particularly, the at least one common chemical element may be aluminum.

For instance, as shown in FIG. 4A, the first metallization layer 142 may include aluminum 150, and the second metallization layer 144 may include an aluminum alloy 152. In some examples, the aluminum alloy 152 may be an aluminum-copper (AlCu) alloy. Additionally and/or alternatively, the aluminum alloy 152 may be an aluminum-magnesium (AlMg) alloy. Additionally and/or alternatively, the aluminum alloy 152 may be an aluminum-beryllium (AlBe) alloy. Furthermore, in some examples, the aluminum alloy 152 may be a ternary aluminum alloy 152 (e.g., a ternary AlCu alloy, a ternary AlMg alloy, a ternary AlBe alloy) that includes a ternary element, such as silicon (Si) and/or cobalt (Co).

Additionally and/or alternatively, as shown in FIG. 4B, the first metallization layer 142 may include the aluminum alloy 152 (hereinafter “first aluminum alloy 152) and the second metallization layer 144 may include a second aluminum alloy 154 that is different from the first aluminum alloy 152. Put differently, the second metallization layer 144 may include any of the aluminum alloys discussed above (e.g., AlCu, AlMg, AlBe, or their ternary compositions) so long as the second aluminum alloy 154 has a different microstructure and grain sizes than the first aluminum alloy 152. It should be understood that the second aluminum alloy 154 may also be a ternary aluminum alloy 154 that includes a ternary element, such as silicon (Si) and/or cobalt (Co).

As one non-limiting example, the first aluminum alloy 152 may be an AlCu alloy. In such examples, the second aluminum alloy 154 may be an AlMg alloy, an AlBe alloy, and/or the corresponding ternary composition.

As another non-limiting example, the first aluminum alloy 152 may be an AlMg alloy. In such examples, the second aluminum alloy 154 may be an AlCu alloy, an AlBe alloy, and/or the corresponding ternary composition.

As another non-limiting example, the first aluminum alloy 152 may be an AlBe alloy. In such examples, the second aluminum alloy 154 may be an AlCu alloy, an AlMg alloy, and/or the corresponding ternary composition.

In some examples, such as that depicted in FIGS. 4C, the first metallization layer 142 and the second metallization layer 144 may not include at least one common chemical element. By way of non-limiting example, referring now to FIG. 4C, the first metallization layer 142 may include aluminum 150, and the second metallization layer 144 may include a copper alloy 156. For instance, in some examples, the copper alloy 156 may be a copper-beryllium (CuBe) alloy (and/or its ternary composition). Additionally and/or alternatively, the copper alloy 156 may be a copper-magnesium (CuMg) alloy (and/or its ternary composition). Furthermore, it should be noted that, although depicted in FIG. 4C as including aluminum 150, the first metallization layer 142 may also include an aluminum alloy (e.g., aluminum alloy 152) without deviating from the scope of the present disclosure.

The example multilayer metallization structures 140 in FIGS. 4A-4C are depicted with four metallization layers for purposes of illustration and discussion. Those having ordinary skill in the art, using the disclosures provided herein, will appreciate that the multilayer metallization structures 140 depicted in FIGS. 4A-4C may include any number of metallization layers (e.g., first metallization layers 142, second metallization layers 144) without deviating from the scope of the present disclosure.

Referring now to FIGS. 4A-4C, the example configurations described above provide for reduced thermomechanical-induced failures associated with thermal cycling (e.g., TC test 128) and aging. For instance, the alloys discussed above (e.g., first aluminum alloy 152, second aluminum alloy 154, copper alloy 156) have a synergic effect that limits the grain growth of the respective metallization layer (e.g., first metallization layer 142, second metallization layer 144). For instance, in the example depicted in FIG. 4A, the aluminum alloy 152 limits grain growth at the interfaces between the first metallization layer 142 and the second metallization layer 144 (e.g., at interface 151) and also increases the recrystallization temperature of the second metallization layer 144. Furthermore, in the example depicted in FIG. 4B, both the first aluminum alloy 152 and the (different) second aluminum alloy 154 limit the grain growth at the interfaces between the first metallization layer 142 and the second metallization layer 144 (e.g., at interface 153) and also increase the recrystallization temperature of both the first metallization layer 142 and the second metallization layer 144. Even further, in the example depicted in FIG. 4C, the copper alloy 156 limits grain growth at the interfaces between the first metallization layer 142 and the second metallization layer 144 (e.g., at interface 155) and also increases the recrystallization temperature of the second metallization layer 144. Hence, the examples depicted in FIGS. 4A-4C increase the yield strength of the individual metallization layers 142, 144 and the multilayer metallization structure 140. In this manner, the example multilayer metallization structures 140 provide for reduced thermomechanical-induced failures.

FIGS. 3, 4A-4C depict example multilayer metallization structures for purposes of illustration and discussion. Those of ordinary skill in the art, using the disclosures provided herein, will understand that different multilayer metallization structure configurations may be used without deviating from the scope of the present disclosure.

FIG. 5 depicts an example semiconductor package 160 of a semiconductor device according to example embodiments of the present disclosure. The semiconductor package 160 may be, for instance, a discrete semiconductor device package. FIG. 5 is provided for purposes of illustration and discussion. Those having ordinary skill in the art, using the disclosures provided herein, will understand that aspects of the present disclosure may be used in a variety of devices and/or applications without deviating from the scope of the present disclosure. Furthermore, FIG. 5 is intended to represent structures for identification and description and is not intended to represent the structures to physical scale.

As shown, the semiconductor package 160 may include a conductive submount 162 (e.g., a patterned conductive substrate, lead frame, clip structure or other power substrate) on which a semiconductor die 164 containing one or more power devices (e.g., transistors, diodes, etc.) is attached using a die-attach material 166. The die-attach material 166 may provide a thermal, mechanical, and electrical connection between the semiconductor die 164 and the conductive submount 162. In some examples, the semiconductor die 164 may also be connected to the conductive submount 162 using wire bonds 168. An encapsulating material 170 (e.g., epoxy mold compound (EMC)) may fill the space around the semiconductor die 164 and the submount 162, thereby defining an encapsulating portion of the semiconductor package 160 and forming a housing. The semiconductor package 160 may further include one or more electrical leads 172 that extend outward from the housing (e.g., outward from the encapsulating material 170).

The semiconductor package 160 may include one or more multilayer metallization structures, such as any of the multilayer metallization structures disclosed herein. It should be understood that the one or more multilayer metallization structures of the semiconductor package 160 may include any of the multilayer metallization structures 140 described above with reference to FIGS. 1, 3-4C.

More particularly, the semiconductor die 164 may include one or more multilayer metallization structures, such as bonding pads (e.g., bonding pads 104 (FIG. 1), etc.). The bonding pads may be coupled to the one or more electrical leads 172 using the wire bonds 168. The wire bonds 168 may be aluminum and/or copper. The wire bonds 168 may have a thickness of about 15 mil to about 20 mil (e.g., about 381 μm to about 508 μm). As noted above, the bonding pads may have a thickness, for instance, of about 4 μm or less. A backside metallization layer (e.g., backside metallization structure 108 (FIG. 1)) on the semiconductor die 164 may be coupled to the submount 162 (e.g., lead frame) using, for instance, the die-attach material 166. The encapsulating material 170 may encapsulate the semiconductor die 164, including its multilayer metallization structures, wire bonds 168, submount 162, and other portions of the semiconductor package 160. In some examples, the encapsulating material 170 (e.g., encapsulating portion) may directly contact the multilayer metallization structures (e.g., bonding pads, backside metallization layer, etc.) of the semiconductor package 160.

FIG. 6 depicts a cross-sectional view of an example semiconductor package of a semiconductor device 180 according to example embodiments of the present disclosure. The semiconductor device 180 of FIG. 6 is a portion of a power module. FIG. 6 is intended to represent structures for identification and description and is not intended to represent the structures to physical scale. The semiconductor device 180 may include a housing 182. The semiconductor device 180 may include a conductive submount 184 (e.g., a patterned conductive submount) on which a semiconductor die 186 is mounted (e.g., using a die-attach material). For instance, the semiconductor die 186 may be mounted on submount 184 using a die-attach material that includes a sintered material, such as sintered silver and/or sintered copper.

The semiconductor device package depicted in FIG. 6 may include one or more multilayer metallization structures, such as any of the multilayer metallization structures disclosed herein (e.g., the multilayer metallization structures 140 described above with reference to FIGS. 1, 3-4C). More particularly, the semiconductor die 186 may include one or more multilayer metallization structures, such as bonding pads 188 (e.g., bonding pads 104 (FIG. 1), etc.). In some embodiments, the semiconductor die 186 may be connected to the conductive submount 184 using wire bonds 190. The conductive submount 184 may be mounted on a base layer 192 (e.g., an insulating layer). An inert gel 194 may fill the space between the semiconductor die 186 and the housing 182.

FIGS. 5-6 depict example semiconductor packages for purposes of illustration and discussion. Those of ordinary skill in the art, using the disclosures provided herein, will understand that different semiconductor package configurations may be used without deviating from the scope of the present disclosure.

Example aspects of the present disclosure are set forth below. Any of the below features or examples may be used in combination with any of the embodiments or features provided in the present disclosure.

One example aspect of the present disclosure is directed to a semiconductor die. The semiconductor die includes a semiconductor structure and a multilayer metallization structure on the semiconductor structure. The multilayer metallization structure includes a first metallization layer and a second metallization layer on the first metallization layer. The second metallization layer has a different grain microstructure than the first metallization layer. The first metallization layer and the second metallization layer include at least one common chemical element.

In some examples, the multilayer metallization structure includes two first metallization layers alternately arranged between two second metallization layers.

In some examples, the multilayer metallization structure includes three first metallization layers alternately arranged between three second metallization layers.

In some examples, the at least one common chemical element is aluminum.

In some examples, the first metallization layer includes aluminum, and the second metallization layer includes an aluminum alloy.

In some examples, the aluminum alloy is one of an aluminum-copper alloy, an aluminum-magnesium alloy, or an aluminum-beryllium alloy.

In some examples, the aluminum alloy is a ternary aluminum alloy, and the ternary aluminum alloy includes a ternary element.

In some examples, the ternary element is one of silicon or cobalt.

In some examples, the first metallization layer includes a first aluminum alloy, and the second metallization layer includes a second aluminum alloy that is different from the first aluminum alloy.

In some examples, the first aluminum alloy is one of an aluminum-copper alloy, an aluminum-magnesium alloy, or an aluminum-beryllium alloy.

In some examples, the second aluminum alloy is one of an aluminum-copper alloy, an aluminum-magnesium alloy, or an aluminum-beryllium alloy.

In some examples, the first metallization layer includes a first grain microstructure having a smallest grain size of greater than about 100 nanometers, and the second metallization layer includes a second grain microstructure having a largest grain size of less than about 100 nanometers.

In some examples, a difference between the smallest grain size of the first grain microstructure and the largest grain size of the second grain microstructure is about 100 nanometers.

In some examples, the smallest grain size of the first grain microstructure is in a range of about 100 nanometers to about 500 nanometers, and the largest grain size of the second grain microstructure is in a range of about 20 nanometers to about 100 nanometers.

In some examples, the multilayer metallization structure is a multilayer metallization stack including a plurality of first metallization layers and a plurality of second metallization layers. Each first metallization layer and each second metallization layer is alternately arranged in a stacked arrangement.

In some examples, the multilayer metallization stack includes at least four metallization layers.

In some examples, the multilayer metallization stack includes at least six metallization layers.

In some examples, the multilayer metallization structure has a combined thickness greater than about 1 micron.

In some examples, the combined thickness of the multilayer metallization structure is about 4 microns.

In some examples, the first metallization layer has a thickness in a range of about 100 nanometers to about 2 microns.

In some examples, the second metallization layer has a thickness in a range of about 100 nanometers to about 2 microns.

In some examples, the semiconductor die is arranged in a semiconductor device package.

In some examples, the semiconductor die is on a submount.

In some examples, the semiconductor device package includes an encapsulating portion.

In some examples, the encapsulating portion directly contacts the multilayer metallization structure.

In some examples, the encapsulating portion includes an epoxy mold compound (EMC).

In some examples, the semiconductor device package includes a passivation layer on the multilayer metallization structure.

In some examples, the passivation layer includes one of silicon nitride or a polymer.

In some examples, the semiconductor device package is one of a discrete semiconductor device package or a power module.

In some examples, the multilayer metallization structure is one or more of an electrode, an interconnect, or a bonding pad for the semiconductor structure.

In some examples, the electrode is one of a gate electrode, a source electrode, or a drain electrode for the semiconductor structure.

In some examples, the semiconductor structure includes a wide bandgap semiconductor.

In some examples, the semiconductor structure includes one of a silicon carbide-based metal-oxide-semiconductor field-effect transistor (MOSFET), a silicon carbide-based Schottky diode, or a Group-III nitride-based high electron mobility transistor (HEMT) device.

Another example aspect of the present disclosure is directed to a semiconductor die. The semiconductor die includes a semiconductor structure and a multilayer metallization structure on the semiconductor structure. The multilayer metallization structure includes a first metallization layer and a second metallization layer on the first metallization layer. A smallest grain size of the first metallization layer is greater than about 100 nanometers, and a largest grain size of the second metallization layer is less than about 100 nanometers.

In some examples, the smallest grain size of the first metallization layer is greater than about 200 nanometers.

In some examples, the second metallization layer includes a different grain microstructure than the first metallization layer.

In some examples, the first metallization layer and the second metallization layer include at least one common chemical element.

In some examples, the multilayer metallization structure includes two first metallization layers alternately arranged between two second metallization layers.

In some examples, the multilayer metallization structure includes three first metallization layers alternately arranged between three second metallization layers.

In some examples, the first metallization layer includes aluminum and the second metallization layer includes an aluminum alloy, and the aluminum alloy is one of an aluminum-copper alloy, an aluminum-magnesium alloy, or an aluminum-beryllium alloy.

In some examples, the first metallization layer includes a first aluminum alloy, and the second metallization layer includes a second aluminum alloy that is different from the first aluminum alloy.

In some examples, the first metallization layer includes aluminum, and the second metallization layer includes a copper alloy.

In some examples, the first metallization layer includes an aluminum alloy.

In some examples, the copper alloy is one of a copper-beryllium alloy or a copper-magnesium alloy.

In some examples, a difference between the smallest grain size of the first metallization layer and the largest grain size of the second metallization layer is about 100 nanometers.

In some examples, the smallest grain size of the first metallization layer is in a range of about 100 nanometers to about 500 nanometers.

In some examples, the smallest grain size of the first metallization layer is in a range of about 200 nanometers to about 300 nanometers.

In some examples, the largest grain size of the second metallization layer is in a range of about 20 nanometers to about 100 nanometers.

In some examples, the multilayer metallization structure is a multilayer metallization stack including a plurality of first metallization layers and a plurality of second metallization layers, and each first metallization layer and each second metallization layer is alternately arranged in a stacked arrangement.

In some examples, the multilayer metallization stack includes at least four metallization layers.

In some examples, the multilayer metallization stack includes at least six metallization layers.

In some examples, the multilayer metallization structure has a combined thickness greater than about 1 micron.

In some examples, the combined thickness of the multilayer metallization structure is about 4 microns.

In some examples, the first metallization layer has a thickness in a range of about 100 nanometers to about 2 microns, and the second metallization layer has a thickness in a range of about 100 nanometers to about 2 microns.

In some examples, the thickness of the first metallization layer is substantially equal to the thickness of the second metallization layer.

In some examples, the thickness of the first metallization layer is different than the thickness of the second metallization layer.

In some examples, the semiconductor die is arranged in a semiconductor device package.

In some examples, the semiconductor device package is one of a discrete semiconductor device package or a power module.

In some examples, the multilayer metallization structure is one or more of an electrode, an interconnect, or a bonding pad for the semiconductor structure.

In some examples, the electrode is one of a gate electrode, a source electrode, or a drain electrode for the semiconductor structure.

In some examples, the semiconductor structure includes a wide bandgap semiconductor.

In some examples, the semiconductor structure includes one of a silicon carbide-based metal-oxide-semiconductor field-effect transistor (MOSFET), a silicon carbide-based Schottky diode, or a Group-III nitride-based high electron mobility transistor (HEMT) device.

Another example aspect of the present disclosure is directed to a semiconductor device package. The semiconductor device package includes a submount and a semiconductor die on the submount. The semiconductor die includes a multilayer metallization structure. The multilayer metallization structure includes a first metallization layer having a thickness in a range of about 100 nanometers to about 2 microns and a second metallization layer having a thickness in a range of about 100 nanometers to about 2 microns on the first metallization layer. The first metallization layer includes aluminum, and the second metallization layer includes an aluminum alloy.

In some examples, the second metallization layer includes a different grain microstructure than the first metallization layer.

In some examples, the first metallization layer and the second metallization layer include at least one common chemical element.

In some examples, the multilayer metallization structure includes two first metallization layers alternately arranged between two second metallization layers.

In some examples, the multilayer metallization structure includes three first metallization layers alternately arranged between three second metallization layers.

In some examples, the aluminum alloy is one of an aluminum-copper alloy, an aluminum-magnesium alloy, or an aluminum-beryllium alloy.

In some examples, the aluminum alloy is a ternary aluminum alloy includes a ternary element.

In some examples, the ternary element is one of silicon or cobalt.

In some examples, the first metallization layer includes a first aluminum alloy, and the second metallization layer includes a second aluminum alloy that is different from the first aluminum alloy.

In some examples, the multilayer metallization structure is a multilayer metallization stack including a plurality of first metallization layers and a plurality of second metallization layers, and each first metallization layer and each second metallization layer is alternately arranged in a stacked arrangement.

In some examples, the multilayer metallization stack includes at least four metallization layers.

In some examples, the multilayer metallization stack includes at least six metallization layers.

In some examples, the multilayer metallization structure has a combined thickness greater than about 1 micron.

In some examples, the combined thickness of the multilayer metallization structure is about 4 microns.

In some examples, the semiconductor device package further includes an encapsulating portion.

In some examples, the encapsulating portion directly contacts the multilayer metallization structure.

In some examples, the encapsulating portion includes an epoxy mold compound (EMC).

In some examples, the semiconductor device package further includes a passivation layer on the multilayer metallization structure.

In some examples, the passivation layer includes silicon nitride.

In some examples, the passivation layer includes a polymer.

In some examples, the polymer includes polyimide.

In some examples, the semiconductor device package is a discrete semiconductor device package.

In some examples, the semiconductor device package is a power module.

In some examples, the multilayer metallization structure is one or more of an electrode, an interconnect, or a bonding pad for the semiconductor die.

In some examples, the electrode is one of a gate electrode, a source electrode, or a drain electrode for the semiconductor die.

In some examples, the semiconductor die includes a wide bandgap semiconductor.

In some examples, the semiconductor die includes one of a silicon carbide-based metal-oxide-semiconductor field-effect transistor (MOSFET), a silicon carbide-based Schottky diode, or a Group-III nitride-based high electron mobility transistor (HEMT) device.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor die, comprising:
a semiconductor structure; and
a multilayer metallization structure on the semiconductor structure, the multilayer metallization structure comprising a first metallization layer and a second metallization layer on the first metallization layer, the second metallization layer having a different grain microstructure than the first metallization layer,
wherein the first metallization layer and the second metallization layer include at least one common chemical element.

2-3. (canceled)

4. The semiconductor die of claim 1, wherein the at least one common chemical element is aluminum.

5. The semiconductor die of claim 1, wherein the first metallization layer comprises aluminum and the second metallization layer comprises an aluminum alloy, and wherein the aluminum alloy is one of an aluminum-copper alloy, an aluminum-magnesium alloy, or an aluminum-beryllium alloy.

6-8. (canceled)

9. The semiconductor die of claim 1, wherein the first metallization layer comprises a first aluminum alloy, and the second metallization layer comprises a second aluminum alloy that is different from the first aluminum alloy.

10-14. (canceled)

15. The semiconductor die of claim 1, wherein the multilayer metallization structure is a multilayer metallization stack comprising a plurality of first metallization layers and a plurality of second metallization layers, and wherein each first metallization layer and each second metallization layer is alternately arranged in a stacked arrangement.

16-17. (canceled)

18. The semiconductor die of claim 1, wherein the multilayer metallization structure has a combined thickness greater than about 1 micron.

19-33. (canceled)

34. A semiconductor die, comprising:
a semiconductor structure; and
a multilayer metallization structure on the semiconductor structure, the multilayer metallization structure comprising a first metallization layer and a second metallization layer on the first metallization layer;
wherein a smallest grain size of the first metallization layer is greater than about 100 nanometers and a largest grain size of the second metallization layer is less than about 100 nanometers.

35-37. (canceled)

38. The semiconductor die of claim 34, wherein the multilayer metallization structure comprises at least two first metallization layers alternately arranged between at least two second metallization layers.

39-41. (canceled)

42. The semiconductor die of claim 34, wherein the first metallization layer comprises aluminum, and the second metallization layer comprises a copper alloy, the copper alloy being one of a copper-beryllium alloy or a copper-magnesium alloy.

43-44. (canceled)

45. The semiconductor die of claim 34, wherein a difference between the smallest grain size of the first metallization layer and the largest grain size of the second metallization layer is about 100 nanometers.

46. The semiconductor die of claim 34, wherein the smallest grain size of the first metallization layer is in a range of about 100 nanometers to about 500 nanometers, and wherein the largest grain size of the second metallization layer is in a range of about 20 nanometers to about 100 nanometers.

47-54. (canceled)

55. The semiconductor die of claim 34, wherein a thickness of the first metallization layer is substantially equal to a thickness of the second metallization layer.

56. The semiconductor die of claim 34, wherein a thickness of the first metallization layer is different than a thickness of the second metallization layer.

57-62. (canceled)

63. A semiconductor device package, comprising:
a submount; and
a semiconductor die on the submount, the semiconductor die comprising a multilayer metallization structure, the multilayer metallization structure comprising a first metallization layer having a thickness in a range of about 100 nanometers to about 2 microns and a second metallization layer on the first metallization layer, the second metallization layer having a thickness in a range of about 100 nanometers to about 2 microns,
wherein the first metallization layer comprises aluminum and the second metallization layer comprises an aluminum alloy.

64-68. (canceled)

69. The semiconductor device package of claim 63, wherein the aluminum alloy is a ternary aluminum alloy comprising a ternary element, and the ternary element is one of silicon or cobalt.

70-76. (canceled)

77. The semiconductor device package of claim 63, further comprising an encapsulating portion directly contacting the multilayer metallization structure, wherein the encapsulating portion comprises an epoxy mold compound (EMC).

78-79. (canceled)

80. The semiconductor device package of claim 63, further comprising a passivation layer on the multilayer metallization structure, wherein the passivation layer comprises one of silicon nitride or a polymer.

81-83. (canceled)

84. The semiconductor device package of claim 63, wherein the semiconductor device package is one of a discrete semiconductor device package or a power module.

85. (canceled)

86. The semiconductor device package of claim 63, wherein the multilayer metallization structure is one or more of an electrode, an interconnect, or a bonding pad for the semiconductor die.

87. (canceled)

88. The semiconductor device package of claim 63, wherein the semiconductor die comprises a wide bandgap semiconductor, the wide bandgap semiconductor comprising one of a silicon carbide-based metal-oxide-semiconductor field-effect transistor (MOSFET), a silicon carbide-based Schottky diode, or a Group-III nitride-based high electron mobility transistor (HEMT) device.

89. (canceled)
